(19) United States
(12) Patent Application Publication
(10) Pub. No.: US 2024/0199216 A1
(43) Pub. Date: Jun. 20, 2024

(54) AN ELECTRICITY GENERATION SYSTEM

(71) Applicant: TUSAS- TURK HAVACILIK VE UZAY SANAYII ANONIM SIRKETI, Kahramankazan/Ankara (TR)

(72) Inventors: Burhan SAHIN, Kahramankazan/Ankara (TR); Murat GUNEL, Kahramankazan/Ankara (TR)

(21) Appl. No.: 18/288,465

(22) PCT Filed: Apr. 26, 2022
(86) PCT No.: PCT/TR2022/050376

§ 371 Date: Oct. 26, 2023

(30) Foreign Application Priority Data
Apr. 29, 2021 (TR) 2021/007301

(51) Int. Cl. B64D 27/24; B64C 27/473; B64D 27/357; B64D 41/00; H02N 2/18; H10N 30/853

(52) U.S. Cl. CPC B64D 27/24; B64C 27/473; B64D 27/357; H02N 2/181; H10N 30/8536; H10N 30/8554; B64D 2041/002

(57) ABSTRACT

The present invention relates to a body (2) provided at air vehicles: at least one rotor (3) extending longitudinally out of the body (2) and rotating around an axis along which it extends: at least one blade (4) connected to the rotor (3), which, upon triggering of the rotor (3), rotates around the axis along which the rotor (3) extends, thus creating an aerodynamic lifting force required for the body (2) to take-off: a blade tip (5) which is located on the blade (4), at the end of a direction along which the blade (4) extends: and at least one plate (6) made of a piezo-electric material, which is located on the blade (4) and enables energy conversion.

The present invention relates to an electricity generation system enabling conversion of motion energy formed by aerodynamic loads, which occur on the blades during the helicopter flight, into electrical energy.

Helicopters are designed for vertical take-off. Such vehicles use blades for take-off, referred as rotary wing systems. Blades, on the other hand, are connected to the rotor and extend outward from the rotor. The blades that the rotor rotates with the control system take different pitch angles during this rotational movement and provide the necessary payload and control for the air vehicle. During the flight, aerodynamic, inertial, static and dynamic loads occur on different axes on the blade. It is seen that these loads are more intense especially in the flutter axis of the blades. As a result of these loadings, the blade is stretched and undergoes elastic deformation. As a result of elastic deformation, motion energy occurs on the blade surface. The word of “piezo” means pressure in Greek. Piezoelectric, on the other hand, is called the ability of a material to change an electric field or electric potential as a result of mechanical pressure applied on the materials. The piezoelectric materials are characterized in that they produce electric current when they are under the influence of a pressure, depending on their crystal structure, and they change shape at a certain level in proportion to the approximate volume when they are under the influence of an electric field. If pressure is applied to an asymmetric ionic crystal with continuous polarization, the distance between the poles decreases and the charge accumulation on its surface increases. Therefore, a potential difference arises between the two terminal points, and if it is combined with a conductor, current flows. Thus, the mechanical effect is converted into electrical magnitude.

U.S. Ser. No. 10/065,731B2, which is included in the known-state of the art, discloses a piezoelectric material that can convert the vibration occurred in said structural parts and/or rotor blades of a helicopter into electrical energy and allows the stiffness of the structural part to be changed with this electrical energy. According to the invention, the structural parts made of piezo electricity are aimed to be used as actuators. In addition, it is able to convert vibration into electrical energy. Said document discloses only the transformation of the vibration that occurs in the vehicle in any situation.

EP2152575B1, which is included in the known-state of the art, discloses a piezoelectric material located at the end of a rotor blade and placed between two electrodes, through which the electrical energy required for the operation of the light emitting diode is obtained. Here, the piezoelectric material creates potential difference between the two electrodes due to the vibrations of the rotor blade to power the light emitting diode, and this voltage is transmitted to the lamp. In the aforementioned patent, the mechanical energy received from the vibration of the rotor is converted into electrical energy and transferred to the diode. The piezoelectric material can be located at the tip of the rotor or in the root area where it is attached to the rotor.

The article titled “Power Harvesting Using Piezo Electric Materials”, which is included in the known-state of the art, discloses conversion of vibration into electrical energy by means of a piezoelectric material. Here, the piezoelectric material is used for a “lag damper” provided in a rotor region of the helicopter, and it is mentioned that the vibrations during the flight are converted into electrical energy and transferred to the electrical systems in the helicopter. Similarly, the places where the loads are distributed are determined by performing deformation analysis on the rotor blade. However, it is stated that it can be used to determine the life of the piezoelectric material on the rotor.

An electricity generation system according to this invention provides an effective, efficient and practical renewable energy production with low energy costs. Thanks to its adaptable structure to changes, its use can be adapted to different designs.

Another object of the invention is to convert the motion energy, which is generated on a blade surface as a result of aerodynamic shear and axial loads, into electrical energy to use it effectively.

The electricity generation system realized to achieve the object of the invention, which is defined in the first claim and other claims dependent thereon, comprises a body provided at air vehicles; at least one rotor extending out of the body and rotating around an axis along which it extends; at least one blade connected to the rotor, which rotates with the rotor around the axis along which the rotor extends, thus obtaining the necessary force to lift the body into the air; a blade tip which is located at the end of a direction along which the blade extends; and at least one plate which is located on the blade and has an energy conversion function due to its piezoelectric structure.

The electricity generation system according to the invention comprises the plate which is fixed on the blade so as to be integrated with an aerodynamic surface of the blade, enables the conversion of mechanical energy caused by elastic deformation of the blade oscillated by aeroelastic forces into electrical energy, and converts the stress and/or strain caused by the elastic deformation on the blade into electrical energy with its piezoelectric structure; a first region (I) located on the blade closer to the blade tip; a second region (II) located on the blade between the rotor and the first region (I), wherein the distance between the first region (I) and the second region (II) is at least as much as the distance between the second region (II) and the rotor, wherein a plurality of plates are fixed on the blade so as to be only in the first region (I) and only in the second region (II).

In an embodiment of the invention, the electricity r generation system comprises the second region (II) located away from the rotor by at least 25% to 35% of the distance between rotor and blade tip; and the first region (I) located away from the rotor by at least 80% to 90% of the distance between rotor and blade tip.

In an embodiment of the invention, the electricity generation system comprises the plate placed in the first region (I) and/or the second region (II) where shear strain and axial strain are equal in at least one point of the aerodynamic surface of the blade during the flight of the air vehicle.

In an embodiment of the invention, the electricity generation system comprises the plate located in any area between the leading edge and the trailing edge.

In an embodiment of the invention, the electricity generation system comprises a first plate located in the first region (I) and/or the second region (II) so as to be closer to the leading edge; and a second plate located to be closer to the trailing edge.

In an embodiment of the invention, the electricity generation system comprises the first plate fixed on the blade at the area close to the blade tip with respect to the second plate.

In an embodiment of the invention, the electricity generation system comprises a plurality of plates located parallel to each other in the first region (I) and/or the second region (II).

In an embodiment of the invention, the electricity generation system comprises the plate form-fitting with the surface of the blade.

In an embodiment of the invention, the electricity generation system comprises the plate, wherein the length of the plate on the axis that the blade extends is greater than the length of the plate on another axis which is substantially perpendicular to the former axis.

In an embodiment of the invention, the electricity generation system comprises at least one electrically powered device located in any part of the body; and a plurality of plates connected to each other in series and/or parallel according to the current and voltage requirements of the device.

In an embodiment of the invention, the electricity generation system comprises the plate capable of producing electric current with the motion energy created under the influence of a force, due to its crystal structure, wherein the plate is made of at least one of the piezoelectric materials such as lead-zirconium-titanium (PZT), quartz (SiO2), barium titanate (BaTiO3), lead zirconate (PbZrO3) or lead titanate (PbTiO3).

In an embodiment of the invention, the electricity generation system comprises at least one cable that transmits the electrical energy produced by the piezoelectric property of the plate; and at least one battery that provides storage of the electrical energy transmitted via the cable and/or feeding of the device through said electrical energy.

In an embodiment of the invention, the electricity generation system comprises the battery that the rotor triggers and rotates, thus storing electrical energy during the movement of the blade, which is in motion.

In an embodiment of the invention, the electricity generation system comprises the plate and/or the battery that supplies devices such as sensors, anti-ice or lighting devices with electrical energy.

In an embodiment of the invention, the electricity generation system comprises the plate removably attached to the blade.

The electricity generation system realized to achieve the object of the present invention is illustrated in the attached drawings, in which:

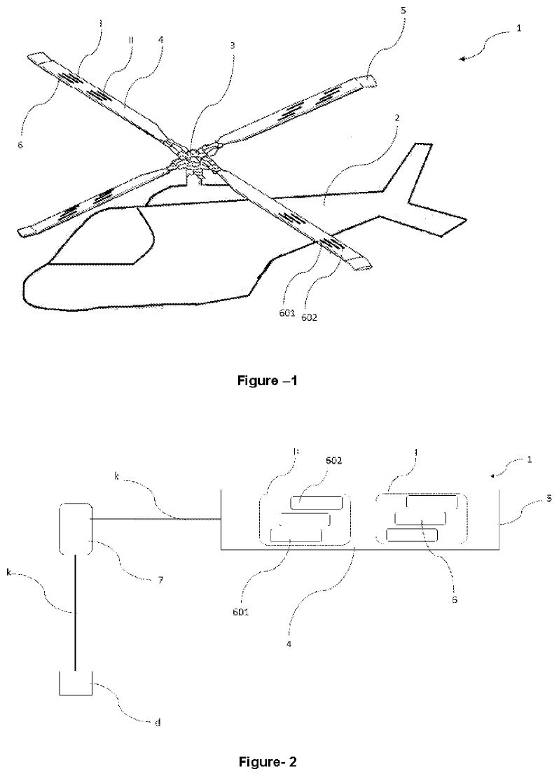

FIG. 1 is a perspective view of the electricity generation system

FIG. 2 is a schematic view of the electricity generation system.

All the parts illustrated in figures are individually assigned a reference numeral and the corresponding terms of these numbers are listed below:
1. Electricity generation system
2. Body
3. Rotor
4. Blade
5. Blade tip
6. Plate
601. First Plate
602. Second Plate
7. Battery
(I) First Region
(II) Second Region
(d) Device
(k) Cable

The electricity generation system (1) comprises a body (2) provided at air vehicles; at least one rotor (3) extending longitudinally out of the body (2) and rotating around an axis along which it extends; at least one blade (4) connected to the rotor (3), which, upon triggering of the rotor (3), rotates around the axis along which the rotor (3) extends, thus creating an aerodynamic lifting force required for the body (2) to take-off; a blade tip (5) which is located on the blade (4), at the end of a direction along which the blade (4) extends; and at least one plate (6) made of a piezo-electric material, which is located on the blade (4) and enables energy conversion.

The electricity generation system (1) according to the invention comprises the plate (6) which is located on the blade (4) so that it is integral with an aerodynamic surface of the blade (4), allows the mechanical energy of elastic deformation on the blade (4) oscillating due to aeroelastic forces to be converted into electrical energy, and enables conversion of the tension and/or strain occurring on the blade (4) due to the elastic deformation of the blade (4) into electrical energy due to its piezo-electric structure; a first region (I) located on the blade (4) closer to the blade tip (5); a second region (II) located on the blade (4) between the rotor (3) and the first region (I), wherein the distance between the first region (I) and the second region (II) is at least as much as the distance between the second region (II) and the rotor (3), wherein a plurality of plates (6) are located on the blade (4) so as to be only in the first region (I) and only in the second region (II) (FIG. 1).

The body (2) is enabled to be lifted into the air and caused to fly since a body (2) provided at air vehicles, at least one rotor (3) extending longitudinally out of the body and rotating around its axis to transfer power and at least one blade (4) rotating around the rotor (3) axis with the power transmitted by the rotor (3) can provide aerodynamic forces. On the blade (4), there is provided a blade tip (5) located at the end of the direction that the blade (4) extends, which is at the furthest distance from the rotor (3). The system comprises at least one plate (6) on the blade (4), which is fixed to the blade (4), made of a piezoelectric material, and capable of converting motion energy into electrical energy and/or converting electrical energy into motion energy.

The plate (6) located on a surface of the blade (4) facing the inside of the blade (4), fixed on the blade (4) so as to be integrated with an aerodynamic surface of the blade (4), and enabling the mechanical energy caused by the elastic deformation on the surface of the blade (4) rotating on the rotor (3) axis during flight to be converted into electrical energy, enables conversion of the stress and/or strain, which is caused by the elastic deformation on the blade (4), to electrical energy due to its piezoelectric structure. There is provided a first region (I) provided on the blade (4) and located closer to the blade tip (5) than the rotor (3); and a second region (II) located on the blade (4) within a region between the rotor (3) and the first region (I). The first region (I) and the second region (II), which have a distance therebetween at least as much as the distance between the second region (II) and the rotor (3), comprise a plurality of plates (6) located on the blade (4) only in the first region (I) and only in the second region (II). Therefore, the motion energy caused by aeroelastic loads such as shear and axial loads acting on the blade (4) can be converted into electrical energy in a low cost and effective manner.

In an embodiment of the invention, the electricity generation system (1) comprises the second region (II) located away from the rotor (3) by at least 25% to 35% of the distance between rotor (3) and blade tip (5); and the first region (I) located away from the rotor (3) by at least 80% to 90% of the distance between rotor (3) and blade tip (5). In the positioning of the first region (I) and the second region (II) which are provided between the rotor (3) and the blade tip (5), the first region (I) is located away from the rotor (3) by at least 80% to 90% of the total length of the blade (4), while the second region (II) is located away from the rotor (3) by at least 25% to 35% of the total length of the blade (4). Therefore, the motion energy caused by aerodynamic loads can be converted into electrical energy in the most effective way.

In an embodiment of the invention, the electricity generation system (1) comprises the plate (6) located in the first region (I) and/or the second region (II) where shear strain and axial strain are equal in at least one point of the aerodynamic surface of the blade (4) during the flight of the air vehicle. During the flight of the body (2), forces such as shear strain and axial strain, in particular, act on the blade (4). The first region (I) and/or the second region (II) are located in regions where shear strain and axial strain are equal. Thus, the motion energy caused by shear strain and axial loads is effectively converted into electrical energy, thereby reducing electricity generation costs.

In an embodiment of the invention, the electricity generation system (1) comprises the plate (6) located on the blade (4) so as to be between the leading edge and the trailing edge. The plate (6) is located on the blade (4) in any region within the region between the leading edge and the trailing edge. Therefore, motion energy is converted into electrical energy more effectively.

In an embodiment of the invention, the electricity generation system (1) comprises a first plate (601) located to be closer to the leading edge; and a second plate (602) located to be closer to the trailing edge, wherein the first plate (601) and the second plate (602) are located in the first region (I) and/or the second region (II). There is provided a first plate (601) located to be closer to the leading edge than the trailing edge in the first region (I) and/or the second region (II) on the pal (4); and a second plate (602) located to be closer to the trailing edge than the leading edge. Therefore, motion energy is handled more effectively to be converted into electrical energy.

In an embodiment of the invention, the electricity generation system (1) comprises the first plate (601) located on the blade (4) closer to the blade tip (5) than the second plate (602). The position of the first plate (601) on the blade (4) is closer to the blade tip (5) than the second plate (602). Therefore, motion energy is converted into electrical energy in a more effective manner.

In an embodiment of the invention, the electricity generation system (1) comprises a plurality of plates (6) located in the first region (I) and/or the second region (II) so as to extend parallel to each other. The plates (6) extend parallel to each other in the first region (I) and the second region (II). In this way, mechanical energy is converted into electrical energy more efficiently.

In an embodiment of the invention, the electricity generation system (1) comprises the plate (6) form-fitting with the surface of the blade (4). The plates (6) have a form-fitting structure with the surface of the blade (4) in order to form a monolithic structure with the surface of the blade (4). Therefore, the aerodynamic structure of the blade (4) can be maintained.

In an embodiment of the invention, the electricity generation system (1) comprises the plate (6), wherein the length of the plate (6) on the axis that the blade (4) extends is greater than its length on the axis which is substantially perpendicular to the former axis. The dimension of the plate (6) on the axis that the blade (4) extends is greater than its length in the perpendicular axis. Therefore, aerodynamic forces acting on the blade are captured more effectively and converted into electrical energy.

In an embodiment of the invention, the electricity generation system (1) comprises at least one electrically powered device (d) located on the body (2); and a plurality of plates (6) connected to each other in series and/or parallel according to the current and voltage requirements of the device (d). The current and voltages of the electrically powered device (d), which is located in any part of the body (2), must be observed in order for the device to be fed correctly and appropriately. In accordance with the current and voltage characteristics, the plates (6) are connected to each other in parallel and/or series. In this way, it is ensured that the electrical energy obtained from the motion energy is used effectively.

In an embodiment of the invention, the electricity generation system (1) comprises the plate (6) capable of producing electric current when under the influence of a force, due to its crystal structure, wherein the plate (6) is made of at least one of the piezoelectric materials such as lead-zirconium-titanium (PZT), quartz (SiO2), barium titanate (BaTiO3), lead zirconate (PbZrO3) or lead titanate (PbTiO3). The plate (6) made of piezoelectric materials such as lead-zirconium-titanium (PZT), quartz (SiO2), barium titanate (BaTiO3), lead zirconate (PbZrO3) or lead titanate (PbTiO3) converts motion energy into electrical energy due to its crystal structure. Thus, motion energy can be efficiently converted into electrical energy.

In an embodiment of the invention, the electricity generation system (1) comprises at least one cable (k) that enables transmission of the electrical energy produced by the plate (6); and at least one battery (7) that provides storage of the electrical energy transmitted via the cable (k) and/or feeding of the device (d) through said electrical energy. When the plate (6) converts the motion energy into electrical energy, it stores the electrical energy in the battery (7) via the cable (k) so that this electrical energy can be stored and used later. When the plate (6) converts the motion energy into electrical energy, it stores the electrical energy in the battery (7) via the cable (k) so that this electrical energy can be stored and used later. Therefore, the motion energy is effectively converted into electrical energy and stored for later use (FIG. 2).

In an embodiment of the invention, the electricity generation system (1) comprises the battery (7) which stores electrical energy during the movement of the blade (4), which is in motion due to the rotational movement of the rotor (3). As long as the rotor (3) moves the blade (4) by making a rotational movement, the mechanical energy is converted into electrical energy. The battery (7) stores this energy throughout the movement. In this way, the continuous storage and use of electrical energy is ensured.

In an embodiment of the invention, the electricity generation system (1) comprises the battery (7) which stores electrical energy during the movement of the blade (4), which is in motion due to the rotational movement of the rotor (3). The battery (7) provides both the storage of energy and the use of the stored electrical energy when necessary. Therefore, electrical energy is stored and used effectively.

In an embodiment of the invention, the electricity generation system (1) comprises the plate (6) and/or the battery (7) that supplies sensors, anti-ice or lighting devices (d). Thus, the stored energy is effectively used where it is needed.

In an embodiment of the invention, the electricity generation system (1) comprises the plate (6) removably attached to the blade (4). In this way, the plate (6) can be easily mounted and can easily adapt to modifications.

1. An electricity generation system (1) comprising:
a body (2) situated at air vehicles;
at least one rotor (3) extending longitudinally out of the body (2) and rotating around an axis along which it extends;
at least one blade (4) connected to the rotor (3), which, upon triggering of the rotor (3), rotates around the axis along which the rotor (3) extends, thus creating an aerodynamic lifting force required for the body (2) to take-off;
a blade tip (5) which is located on the blade (4), at the end of a direction along which the blade (4) extends; and
at least one plate (6) made of a piezoelectric material, which is located on the blade (4) and enables energy conversion, wherein the plate (6) is located on the blade (4) so that it is monolithic with an aerodynamic surface of the blade (4), allows the mechanical energy of elastic deformation on the blade (4) oscillating due to aeroelastic forces to be converted into electrical energy, and enables conversion of the tension and/or strain occurring on the blade (4) due to the elastic deformation of the blade (4) into electrical energy due to its piezoelectric structure; a first region (I) located on the blade (4) closer to the blade tip (5); a second region (II) located on the blade (4) between the rotor (3) and the first region (I), wherein the distance between the first region (I) and the second region (II) is at least as much as the distance between the second region (II) and the rotor (3), wherein a plurality of plates (6) are located on the blade (4) so as to be only in the first region (I) and only in the second region (II).

2. The electricity generation system (1) according to claim 1, wherein the second region (II) is located away from the rotor (3) by at least 25% of the distance between rotor (3) and blade tip (5); and wherein the first region (I) is located away from the rotor (3) by at least 80% of the distance between rotor (3) and blade tip (5).

3. The electricity generation system (1) according to claim 1, wherein the plate (6) is located in the first region (I) and/or the second region (II) where shear strain and axial strain are equal in at least one point of the aerodynamic surface of the blade (4) during the flight of the air vehicle.

4. The electricity generation system (1) according to claim 1, wherein the plate (6) is located between the leading edge and the trailing edge of the blade (4).

5. The electricity generation system (1) according to claim 1, wherein a first plate (601) is located to be closer to the leading edge, and wherein a second plate (602) is located to be closer to the trailing edge, and wherein the first plate (601) and the second plate (602) are located in the first region (I) and/or the second region (II).

6. The electricity generation system (1) according to claim 5, characterized by wherein the first plate (601) is located on the blade (4) closer to the blade tip (5) than the second plate (602).

7. The electricity generation system (1) according to claim 1, wherein a plurality of the plates (6) are located in the first region (I) and/or the second region (II) so as to extend parallel to each other.

8. The electricity generation system (1) according to claim 1, wherein the plate (6) is form-fitting with the surface of the blade (4).

9. The electricity generation system (1) according to the plate (6) claim 1, wherein a length of the plate (6) on the axis that the blade (4) extends is greater than a length of the plate (6) on the axis which is substantially perpendicular to the former axis.

10. The electricity generation system (1) according to claim 1, comprising at least one electrically powered device (d) located on the body (2); and where a plurality of the plates (6) are connected to each other in series and/or parallel according to the current and voltage requirements of the device (d).

11. The electricity generation system (1) according to claim 1, wherein the plate (6) produces electric current when under the influence of a force, due to its crystal structure, wherein the plate (6) is made of at least one of the piezoelectric materials such as lead-zirconium-titanium (PZT), quartz (SiO2), barium titanate (BaTiO3), lead zirconate (PbZrO3) or lead titanate (PbTiO3).

12. The electricity generation system (1) according to claim 10, comprising:
at least one cable (k) that provides transmission of the electrical energy produced by the plate (6); and
at least one battery (7) that provides storage of the electrical energy transmitted via the cable (k) and/or feeding of the device (d) through said electrical energy.

13. The electricity generation system (1) according to claim 12, wherein the battery (7) stores electrical energy during the movement of the blade (4), which is in motion due to the rotational movement of the rotor (3).

14. The electricity generation system (1) according to claim 12, wherein the plate (6) and/or the battery (7) supplies sensors, anti-ice or lighting devices (d).

15. (canceled)
